(19) United States
(12) Patent Application Publication
(10) Pub. No.: US 2013/0003466 A1
(43) Pub. Date: Jan. 3, 2013

(54) APPLICATION CIRCUIT AND OPERATION METHOD OF SEMICONDUCTOR DEVICE

(75) Inventors: Riichiro Shirota, Hsinchu (TW); Hiroshi Watanabe, Hsinchu (TW)

(73) Assignee: NATIONAL CHIAO TUNG UNIVERSITY, Hsinchu City (TW)

(21) Appl. No.: 13/533,975

(22) Filed: Jun. 27, 2012

(30) Foreign Application Priority Data
Jun. 28, 2011 (TW) 100122638

(51) Int. Cl. H01L 29/788; G11C 16/02

(52) U.S. Cl. 365/185.29; 257/316; 257/E29.3

(57) ABSTRACT

An application circuit and an operation method of a semiconductor device are provided. A leakage current among a control gate diffusion layer, a source diffusion layer and a drain is reduced by adjusting biases applied on a double well region, so as to reduce the product cost and improve the accuracy of a battery-less electronic timer that uses the semiconductor device.

### CROSS-REFERENCE TO RELATED APPLICATION

This application claims the priority benefit of Taiwan application serial no. 100122638, filed on Jun. 28, 2011. The entirety of the above-mentioned patent application is hereby incorporated by reference herein and made a part of this specification.

### BACKGROUND

1. Field of the Invention

The present invention relates to a semiconductor device, and an operation method and an application circuit thereof, and more particularly to a semiconductor device applied in a battery-less electronic timer, and an operation method and an application circuit thereof.

2. Description of Related Art

In the Japanese Patent JP3959340, a solid-state aging device (SSAD) that includes a circuit for controlling expiration has been proposed as the integrated circuit of a battery-less electronic timer (IBLET). The fundamental idea of controlling expiration is to suppress the error in timing caused by anomalous charge loss, as shown in FIGS. 1A to 1D. Three time cells 102, 104, and 106 in FIGS. 1A to 1D are used to exemplify the above concept. The lifetimes of the three cells 102, 104, and 106, where in each lifetime the current flowing between terminals T1 and T2, are respectively short, middle, and long. Further, these three time cells 102, 104, and 106 are connected in parallel between two terminals (terminal T1 and terminal T2). The currents through these time cells disappear in sequence of the lifetime of the time cells.

In the initial state, as shown in FIG. 1A, the currents flow through all the time cells between the terminals. As the time cell with the shortest lifetime 102 among the three time cells expires firstly progressively with time, the currents through the shortest lifetime 102 disappears, while the currents flow through the remaining time cells with the middle lifetime 104 and with the long lifetime 106, as shown in FIG. 1B. As time elapses further, the time cells expires in sequence; and gradually, the currents flow through only the time cell with the longest lifetime 106 (as shown in FIG. 1C). When the lifetime of the time cell with the longest lifetime 106 expires, the currents through the terminals T1 and T2 disappear, which implies the connection between the terminals T1 and T2 is terminated. Accordingly, a state of electrical connection between the terminals T1 and T2 is determined by the time cell with the longest lifetime 106 among the parallel-connected time cells between the terminals T1 and T2.

Since main reliability issue of time cell is an anomalous charge loss, which results in the degradation of the lifetime of the time cell, it can be regarded that the resultant lifetime is determined by the time cell without the anomalous charge loss as long as the number of parallel-connected time cells is large enough. Therefore, when a large number of time cells are connected in parallel, the lifetime shall be controllable.

In the prior art, there are basically two types of time cell structure and fabrication method thereof. One type of time cell is the single polysilicon time cell, which can be fabricated along with the CMOS fabrication line (U.S. Pat. No. 7,652,317, US Patent Application Publication US2008/0079057), as shown in FIGS. 2 and 3. The equivalent circuit model of this type of time cell is illustrated in FIG. 4. As shown in FIG. 4, the gate capacitance Cg (an equivalent capacitance between the floating gate FG and the silicon surface composed of N-type source NS, the N-type drain ND, and the P-type substrate PSUB) is smaller than the control capacitance Cc (the equivalent capacitance between the floating gate FG and the N-type control gate NCG). Another type of the time cell is the double polysilicon time cell, which can normally be fabricated along with the fabrication of non-volatile memory cells (US Patent Application Publication US2009/0218613). The equivalent circuit model of a double polysilicon time cell is illustrated in FIG. 5.

In a single polysilicon time cell structure, the N-type control gate NCG and the N-type source NS, the N-type drain ND on the surface of the P-type substrate PSUB are fabricated as diffusion layers. The shallow-trench-isolation (STI) 202 or the local oxidation of silicon (LOCOS) is disposed to electrically isolate the N-type control gate NCG from the N-type source NS and N-type drain ND. The fabrication of a typical shallow-trench isolation structure can be achieved by etching a shallow trench in the substrate between the N-type control gate NCG and the other diffusion layers (the N-type source NS and the N-type drain ND), followed by filling the shallow trench with an isolation material, such as silicon dioxide or other dielectric materials. The fabrication of a typical LOCOS structure can be achieved by depositing a mask, such as silicon nitride (Si₃N₄) on a blank silicon wafer, followed by patterning the mask via photolithography and forming a silicon oxide layer (SiO₂) on the exposed silicon surface (exposed by an etching technique). This silicon oxide layer may serve to electrically isolate the N-type control gate NCG from the other diffusion layers (the N-type source NS and the N-type drain ND).

Major issue of anomalous charge loss of time cell, which is mentioned above, is trap located in insulating layer adopted in time cell. This trap sometimes becomes active to increase the leakage of electron through the insulating layer, and thereby causes the anomalous charge loss of time cell. (H. Watanabe, et. al., IEEE Trans. Elec. Dev. Vol. 58, issue 3, pp. 792-797.).

### SUMMARY OF THE DISCLOSURE

The present invention is directed to a semiconductor device, and an operation method and an application circuit thereof, in which the accuracy of a battery-less electronic timer using the semiconductor device is enhanced.

An exemplary embodiment of the present invention provides a semiconductor device including a first conductive-type semiconductor substrate, a gate dielectric layer, a floating gate, a first conductive type well, a second conductive type well, a second conductive type source diffusion layer, a second conductive type drain diffusion layer and a second conductive type control gate diffusion layer. The gate dielectric layer is formed on the first conductive type semiconductor substrate. The floating gate is formed on the gate dielectric layer. The second conductive type well is formed in the first conductive type semiconductor substrate. The first conductive type well is formed in the second conductive type well. The second conductive type source diffusion layer and the second conductive type drain diffusion layer are formed respectively at two sides of the floating gate in the first conductive type semiconductor substrate. The second conductive type source diffusion layer, the second conductive type drain diffusion layer and the floating gate are formed to compose a second conductive type transistor, wherein the second conductive type transistor is configured at the exterior of the second conductive type well. Additionally, the second conductive type control gate diffusion layer is formed in the first conductive type well.

According to an exemplary embodiment of the invention, the above semiconductor device further includes a source contact layer, a drain contact layer, a control gate contact layer, and at least a second well contact layer, a first well contact layer, and a substrate contact layer. The source contact layer is disposed on the second conductive type source diffusion layer. The drain contact layer is disposed on the second conductive type drain diffusion layer. The control gate contact layer is disposed on the second conductive type gate diffusion contact layer. The second well contact layer is disposed on the second conductive type well. The first well contact layer is disposed on the first conductive type well. The substrate contact layer is disposed on the first conductive type semiconductor substrate.

According to an exemplary embodiment of the invention, the second well contact layer is configured between the second conductive type transistor and the first conductive type well.

According to an exemplary embodiment of the invention, the overlapping area of the floating gate and the second conductive type control gate diffusion layer is greater than the overlapping area of the floating gate and the second conductive type transistor's channel area on the surface of the first conductive type semiconductor substrate between the source contact layer and the drain contact layer.

The present invention provides an operation method of a semiconductor device. To read the charge state of the semiconductor device, a sweep read bias on the control gate contact layer; grounding the source contact layer and the substrate contact layer; applying a positive bias to the drain contact layer, applying a negative bias to the first well contact layer; applying a positive bias to or grounding the second well contact layer. To program the device, a first bias is applied to the control gate contact layer, while the source contact layer, the drain contact layer, and the substrate contact layer are grounded; a second bias is applied to the first well contact layer and the second well contact layer or the first well contact layer and the second well contact layer are grounded. The first bias is greater than ground and the second bias is greater than ground or equal to the ground and smaller than or equal to the first bias. To erase the semiconductor device, a negative bias is applied to the control gate contact layer and the first well contact layer, a positive bias is applied to the source contact layer and the drain contact layer, the second well contact layer and the substrate contact layer are grounded.

The present invention also provides a semiconductor device including a first conductive type semiconductor substrate, a gate dielectric layer, a floating gate, a second conductive type well, a first conductive type well, a second conductive type source diffusion layer, a second conductive type drain diffusion layer, and a second conductive type control gate diffusion layer. The gate dielectric layer is formed on the first conductive type semiconductor substrate. The floating gate is formed on the gate dielectric layer. The second conductive type well is formed in the first conductive type semiconductor substrate. The first conductive type well is formed in the second conductive type well. The second conductive type complementary capacitor gate diffusion layer is formed in the first conductive type semiconductor substrate, outside the second conductive well. The second conductive type source diffusion layer and the second conductive type drain diffusion layer are respectively formed at two sides of the floating gate in the first conductive type semiconductor substrate. The second conductive type source diffusion layer, the second conductive type drain diffusion layer, and the floating gate are formed to compose a second conductive type transistor, wherein the second conductive type transistor is configured between the second conductive type well and the second conductive type complementary capacitor gate diffusion layer. Moreover, the second conductive type control gate diffusion layer is formed in the first conductive type well.

According to an exemplary embodiment of the invention, the above semiconductor device further includes a complementary capacitor gate contact layer, disposed on the second conductive type complementary capacitor gate diffusion layer.

The present invention provides an operation method of the semiconductor device. To read the charged state of the semiconductor device, a sweep bias is applied to the control gate and a positive bias is applied to the drain contact layer, while the source contact layer, the first well contact layer, the second well contact layer, the complementary capacitor gate contact layer and the substrate contact layer are grounded. To program the semiconductor device, a first bias is applied to the control gate contact layer and a second bias is applied to the source contact layer, the drain contact layer, the first well contact layer, and the second well contact layer, while the complementary capacitor gate contact layer and the substrate contact layer are grounded. Further, the first bias is greater than ground and the second bias is greater than ground and is less than the first bias. To erase the semiconductor device, a negative bias is applied to the control gate contact layer and the first well contact layer, while the source contact layer, the drain contact layer, the second well contact layer, and the substrate contact layer are grounded. Moreover, a second bias is applied to the complementary capacitor gate contact layer.

The invention provides a semiconductor device including a first conductive-type semiconductor substrate, a gate dielectric layer, a floating gate, a second conductive type well, a first conductive type well, a second conductive type source diffusion layer, a second conductive type drain diffusion layer, and a second conductive type control gate diffusion layer. The gate dielectric layer is formed on the first conductive type semiconductor substrate. The floating gate is formed on the gate dielectric layer. The second conductive type well is formed on the first conductive type semiconductor substrate. The first conductive type well is formed in the second conductive type well. The second conductive type complementary capacitor gate diffusion layer is formed in the first conductive type well. The second conductive type control gate diffusion layer is formed in the first conductive type semiconductor substrate and at the exterior of the second conductive type well. The second conductive type source diffusion layer and the second conductive type drain diffusion layer are respectively formed at two sides of the floating gate in the first conductive type semiconductor substrate, wherein the second conductive type source diffusion layer, the second conductive type drain diffusion layer, and the floating gate are formed to compose a second conductive type transistor. Further, the second conductive type transistor is configured between the second conductive type well and the second conductive type control gate diffusion layer.

The invention provides an operation method of the semiconductor device. To read the charged state of the semiconductor device, a sweep bias is applied to the control gate contact layer, a positive bias is applied to the drain contact layer, and the first well contact layer, the second well contact layer, the complementary capacitor gate contact layer, and the substrate contact layer are grounded. To program the semiconductor device, a positive bias is applied to the control gate contact layer, and a negative bias is applied to the first well contact layer and the complementary capacitor gate contact layer, while the source contact layer, the drain contact layer, the second well contact layer, and the substrate contact layer are grounded. To erase the semiconductor device, a first bias is applied to the complementary capacitor gate contact layer and a second bias is applied to the first well contact layer and the second well contact layer, while the control gate contact layer, the source contact layer, the drain contact layer, and the substrate contact layer are grounded. Further, the first bias is greater than ground and the second bias is greater than ground and smaller than the first bias.

The invention also provides a parallel chain circuit model including a plurality of the above semiconductor devices, wherein the source contact layer and the drain contact layer of each semiconductor device are respectively connected to the first terminal and the second terminal.

The invention also provides serial-connected parallel-chain circuits composed of a plurality of the above semiconductor devices, wherein these parallel-chain circuits are connected in serial.

The invention also provides a serial chain circuit model including a plurality of the above semiconductor devices serially connected together, wherein the drain contact layer of the first semiconductor device in the serial chain circuit model is electrically connected to the first terminal, while the source contact layer of the last semiconductor device in the serial chain circuit model is electrically connected to the second terminal.

The invention also provides parallel-connected serial-chain circuits composed of a plurality of the above semiconductor devices, wherein these serial-chain circuits are connected in parallel.

In order to the make the aforementioned and other objects, features and advantages of the present invention comprehensible, a preferred embodiment accompanied with figures are described in detail below.

### BRIEF DESCRIPTION OF THE DRAWINGS

FIGS. 1A-1D are schematic diagrams illustrating an effective control circuit according to the prior art.

FIGS. 2 to 3 are schematic diagrams illustrating the structure of a time cell according to the prior art.

FIG. 4 is an equivalent circuit diagram of the time cell structure of FIG. 3.

FIG. 5 is an equivalent circuit diagram of the structure of a double polysilicon time cell according to the prior art.

FIG. 6A is a top view diagram of a semiconductor device according to an exemplary embodiment of the invention.

FIGS. 6B to 6D are cross-sectional views of FIG. 6A along the cutting lines A-A′, B-B′, C-C′, respectively.

FIG. 7 is a top view diagram of a semiconductor device according to another exemplary embodiment of the invention.

FIG. 8 is a current-vs-time diagram illustrating the current flow between the N-type source diffusion layer 612 and the N-type drain diffusion layer 614 of the exemplary embodiment in FIG. 6A as a function of time.

FIG. 9A to 9D are schematic diagrams illustrating parallel-chain circuit models according to exemplary embodiments of the invention.

FIG. 10A to 10D are schematic diagrams illustrating serial-connected circuits of parallel chain circuits according to exemplary embodiments of the invention.

FIG. 11 is another current-vs-time diagram illustrating the current flow between the N-type source diffusion layer 612 and the N-type drain diffusion layer 614 of the exemplary embodiment in FIG. 6A as a function of time.

FIG. 12A to 12D are serial-chain circuit models according to exemplary embodiments of the invention.

FIG. 13A to 13D are schematic diagram showing parallel-connected serial-chain circuit models according to exemplary embodiments of the invention.

FIG. 14A is a top view diagram of a semiconductor device according to another exemplary embodiment of the invention.

FIGS. 14B to 14C are cross-sectional views of FIG. 14A along the cutting lines A-A′, B-B′, respectively.

FIG. 15 is an equivalent circuit model of the semiconductor device 1400.

FIG. 16A is a top view diagram of a semiconductor device according to another exemplary embodiment of the invention.

FIG. 16B is a cross-sectional view diagram of FIG. 16A along the cutting line A-A′.

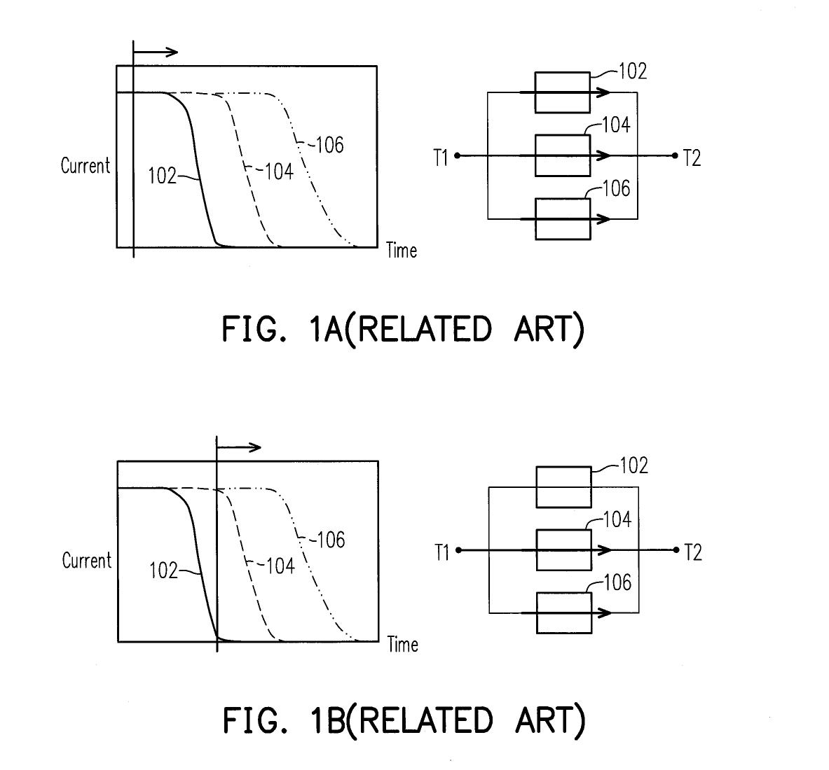

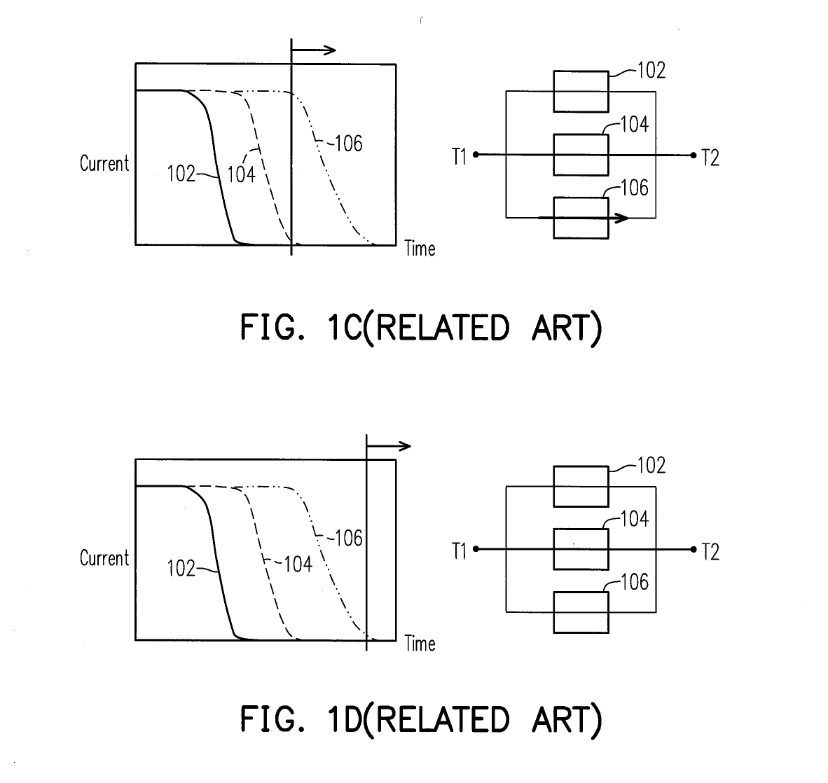

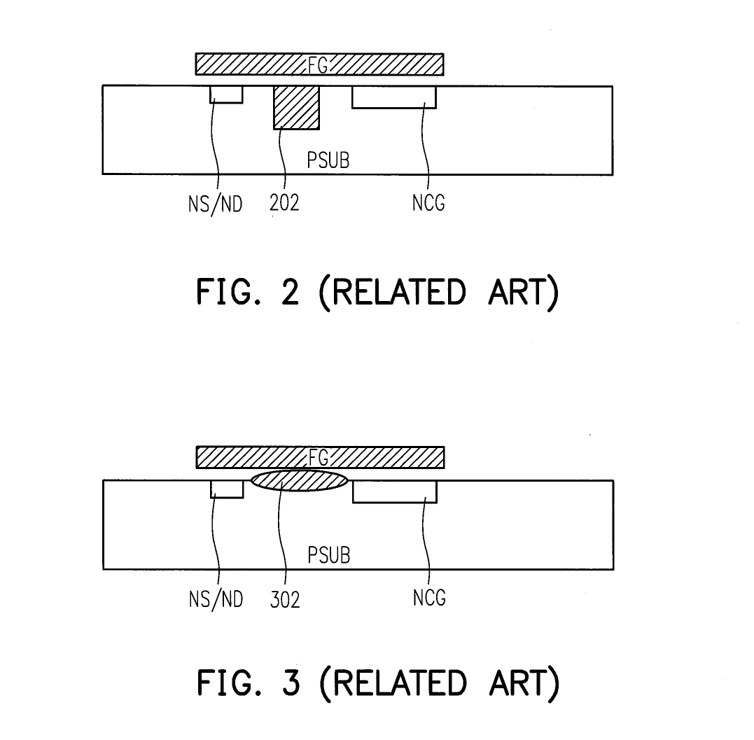

### DESCRIPTION OF EMBODIMENTS

Reference now is made to the accompanying drawings to describe the specific embodiments and examples of the invention. Whenever possible, the same reference numbers are used in the drawings and the description to refer to the same or like parts.

### First Embodiment

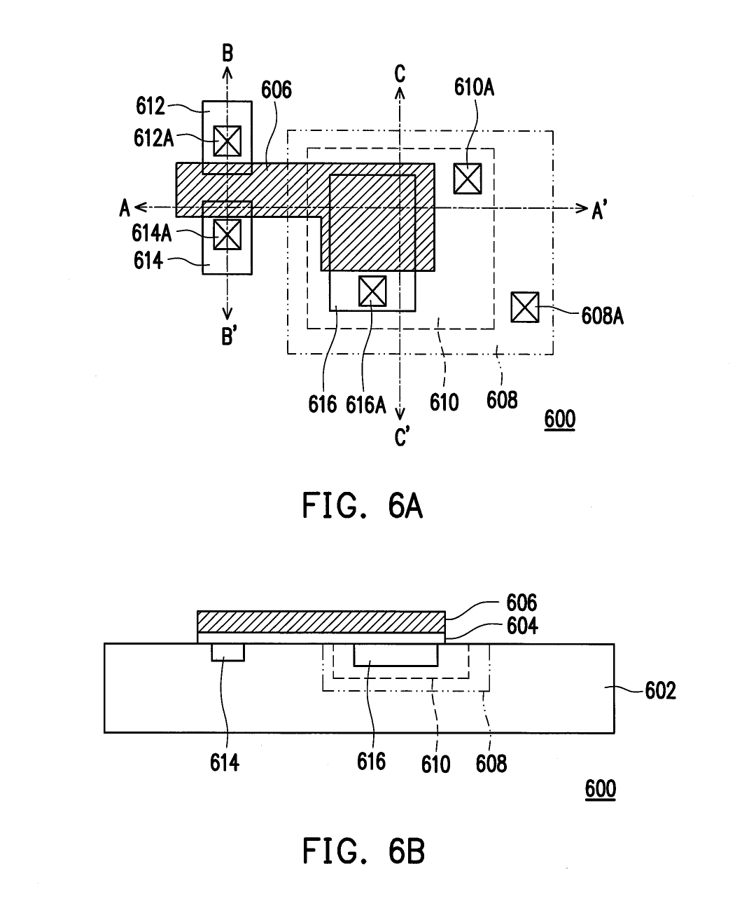

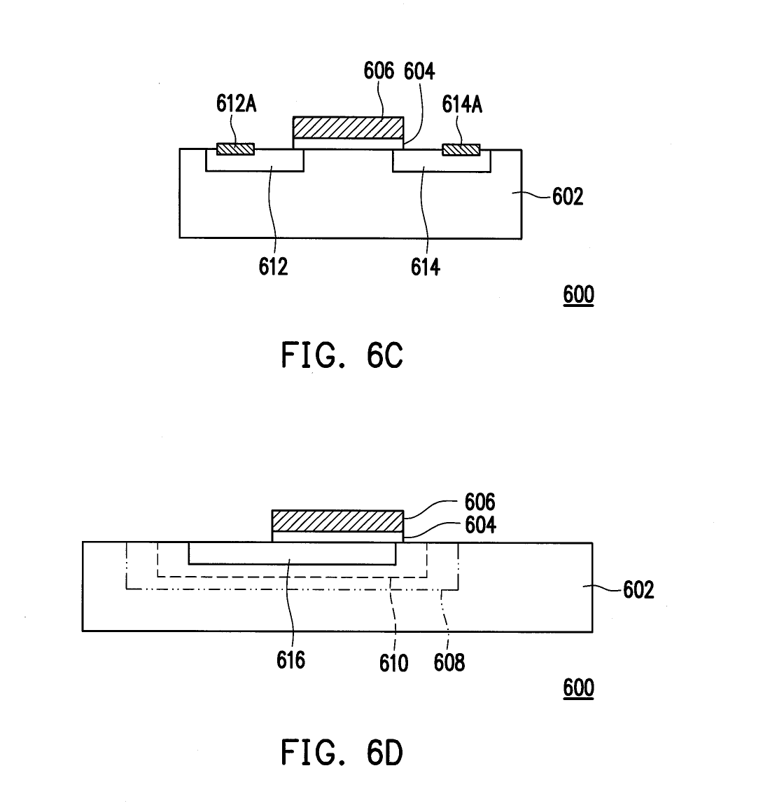

FIG. 6A is a top view diagram of a semiconductor device according to an exemplary embodiment of the invention. FIGS. 6B to 6D are cross-sectional views of FIG. 6A along the cutting lines A-A′, B-B′, C-C′, respectively. Referring concurrently to FIGS. 6A to 6D, the semiconductor device 600 includes a first conductive type semiconductor substrate 602, a gate dielectric layer 604, a floating gate 606, a second conductive type well 608, a first conductive type well 610, a second conductive type source diffusion layer 612, and a second conductive type drain diffusion layer 614, and a second conductive type control gate diffusion layer 616. The second conductive type source diffusion layer 612, the second conductive type drain diffusion layer 614 and the floating gate 606 are formed to compose a second conductive type transistor, and the second conductive type transistor is configured outside the second conductive type well. The overlapping area of the floating gate 606 and the second conductive-type control gate diffusion layer 616 is greater than the overlapping region of the floating gate 606 and others (612, 614, 608, 610).

Moreover, the semiconductor device 600 also includes a source contact layer 612A, a drain contact layer 614A, a control gate contact layer 616A, at least a second well contact layer 608A, a first well contact layer 610A and a substrate contact layer (not shown). The source contact layer 612A is disposed on the second conductive type source diffusion layer 612. The drain contact layer 614A is disposed on the second conductive type drain diffusion layer 614. The control gate contact layer 616A is disposed on the second conductive type control gate diffusion layer 616. The second well region contact layer 608A is disposed on the second conductive type well 608. The first well contact layer 610A is disposed on the first conductive type well 610. The substrate contact layer is disposed at the first conductive type semiconductor substrate.

Assuming the first conductive type is P-conductive type, the second conductive type is N-conductive type, the first conductive type and the second conductive type are respectively described as P-type and N-type in the following disclosure.

In the semiconductor device 600, the gate dielectric layer 604 is formed on the P-type semiconductor substrate 602, the floating gate 606 is formed on the gate dielectric layer 604, the N-type well 608 is formed in the P-type semiconductor substrate 602, the P-type well 610 is configured in the N-type well 608, and the N-type control gate diffusion layer 616 is formed in the P-type well 610. Moreover, the N-type source diffusion layer 612 and the N-type drain diffusion layer 614 are respectively formed in the P-type semiconductor layer 602 at two sides of the floating gate 606. The N-type source diffusion layer 612, the N-type drain diffusion layer 614, and the floating gate 606 together form an N-type transistor, and this N-type transistor is configured at the exterior of the N-type well 608.

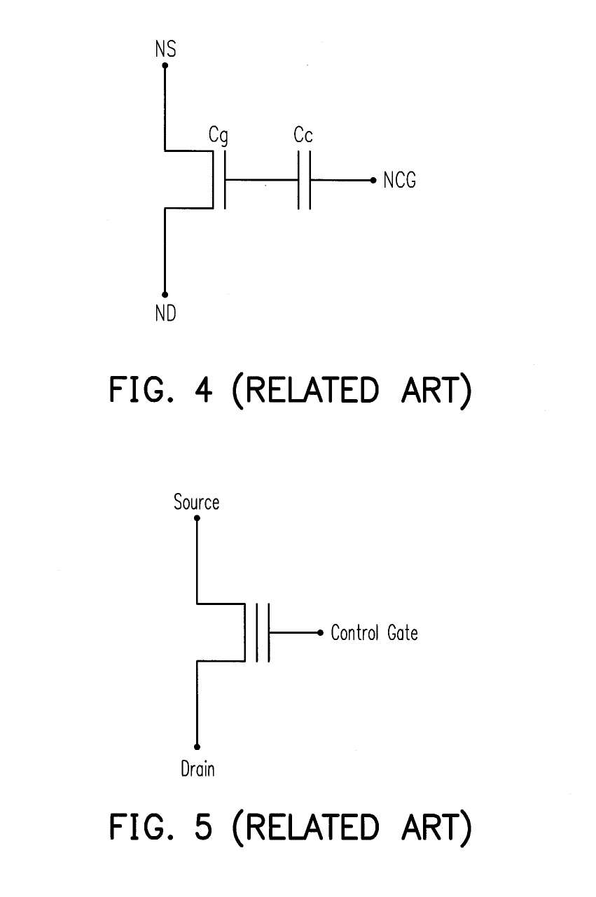

During the operation of the semiconductor device 600, of voltage pulse is applied to each contact layer to perform the read, program and erase operations of the semiconductor device 600. By controlling the biases applied to each contact layer and adjusting the doping profiles in the P-type semiconductor substrate 602, the leakage current between the N-type control gate diffusion layer 616 and the N-type transistor can be reduced. The equivalent circuit of the semiconductor device 600 in this exemplary embodiment as shown in FIG. 4. Since the overlapping area of the floating gate 606 and the N-type control gate diffusion layer 616 is greater than the overlapping area between the floating gate 606 and the N-type transistor's channel area on the surface of the P-type semiconductor substrate 602 between the N-type source diffusion layer 612 and the P-type drain diffusion layer 614, the control capacitance Cc (the equivalent capacitance between the floating gate 606 and the N-type control gate diffusion layer 616) is greater than the gate capacitance Cg (composed of the equivalent capacitance formed of the floating gate 606 and the channel region between the source contact layer 612A and the drain contact layer 614A).

More specifically, when the semiconductor device 600 in FIGS. 6A to 6D performs the read, program and erase operations, the biases being applied to the contact layers are shown in Table 1 as follows:

TABLE 1

| | Read | Program | Erase |
|---|---|---|---|
| Control gate contact layer | Sweep | 1^{st} bias | Negative |
| Source contact layer | Ground | Ground | Positive |
| Drain contact layer | Positive | Ground | Positive |
| First well region contact layer | Negative | 2^{nd} bias or | Negative |
| | | Ground | |
| Second well region contact layer | Positive or | 2^{nd} bias or | Ground |
| | Ground | Ground | |
| Substrate contact layer | Ground | Ground | Ground |

As shown in Table 1 above, to read the threshold voltage shift of the semiconductor device 600, a sweep bias is applied to the control gate contact layer 616A, while a positive bias is applied to the drain contact layer 614A. A negative bias is applied to the first well contact layer 610A to prevent a forward bias between the P-type well 610 and the N-type well 608. Moreover, a positive bias or ground is applied to the second well contact layer 608A, while the source contact layer 612A and the substrate contact layer (not shown) are grounded.

To program the semiconductor device 600, a first bias is applied to the control gate contact layer 616A. Concurrently, a second bias or ground is applied to the first well contact layer 610A and the second well contact layer 608A, wherein the first bias is greater than ground, while the second bias is great than or equal to ground and smaller than or equal to the first bias. Further, the source contact layer 612A, the drain contact layer 614A and the substrate contact layer (not shown) are grounded. Since the control capacitance Cc is relatively larger than the gate capacitance Cg, electrons are injected from the P-type semiconductor substrate 602, the N-type source diffusion layer 612 and N-type drain diffusion layer 614 into the floating gate 606. Accordingly, the threshold voltage of the semiconductor device 600 is increased.

To erase the semiconductor device 600, a negative bias is applied to the control gate contact layer 616A and the first well contact layer 610A. Concurrently, a positive bias is applied to the source contact layer 612A and the drain contact layer 614A. Additionally, the second well contact layer 608A and the substrate contact layer are grounded. Accordingly, electrons are released from the floating gate 606 to the channel between the N-type source diffusion layer 612 and the N-type drain diffusion layer 614 to lower the threshold voltage of the semiconductor device 600.

As an example, the biases that are applied to the various contact layers in the semiconductor device 600 in the exemplary embodiment illustrated in FIGS. 6A to 6D are summarized in Table 2 below:

| | Read | | Program | Erase |
|---|---|---|---|---|
| Control gate contact layer | −2 to 2 | V | 10 V | −8 V |
| Source contact layer | 0 | V | 0 V | 2 V |
| Drain contact layer | 0.5 | V | 0 V | 2 V |
| First well region contact layer | −2 | V | 5 V | −8 V |
| Second well region contact layer | 0 | V | 5 V | 0 V |
| Substrate contact layer | 0 | V | 0 V | 0 V |

As shown in Table 2, to read the threshold voltage shift of the semiconductor device 600, a sweep read is performed by applying a voltage of −2 V to 2 V to the control gate contact layer 616A and 0.5 V is concurrently applied to the drain contact layer 614A. The biases applied to the source contact layer 612A, the second well contact layer 608A and the substrate contact layer are respectively 0 V. To program the semiconductor device 600, the control gate contact layer 616A is applied with 10V and the first well contact layer 610A and the second well contact layer 608A are respectively applied with 5V, while the bias of other contact layers are 0 V. Since the floating gate 606 is negatively charged by programming, the threshold voltage of the semiconductor device 600 increases. To erase the semiconductor device 600, −8V is applied to the control gate contact layer 616A and the first well contact layer 610A, while the second well contact layer 608A and the substrate contact layer are respectively 0 V. Further, a bias of 2V is applied to the source contact layer 612A and the drain contact layer 614A. In this case, electrons flow from the floating gate FG 606 to the N-type drain diffusion layer 614 and the N-type source diffusion layer 612, and the threshold voltage of the semiconductor device 600 is decreased. It is also preferable that a bias of 10 V is applied to source and drain contact layers (612A and 614A), while a bias of 8V is applied to second well contact layer 610A and substrate contact layer. The control gate contact layer 616A and the first well contact layer 610A are grounded.

It is worthy to note that, in some exemplary embodiments, the operation voltages in Table 2 for erasing the semiconductor device 600, the source contact layer 612A and the drain contact layer 614A are grounded (in other words, in the semiconductor device 600, only the control gate contact layer 616A and the first well contact layer 610A are applied with a negative bias, while the bias of other contact layers is 0V). Since the control capacitance Cc is greater than the gate capacitance Cg, electrons flow from the floating gate 606 to the P-type semiconductor substrate 602, the N-type diffusion layer 612 and the N-type drain diffusion layer 614. Accordingly, the floating gate 606 is positively charged to lower the threshold voltage of the semiconductor device 600.

### Second Embodiment

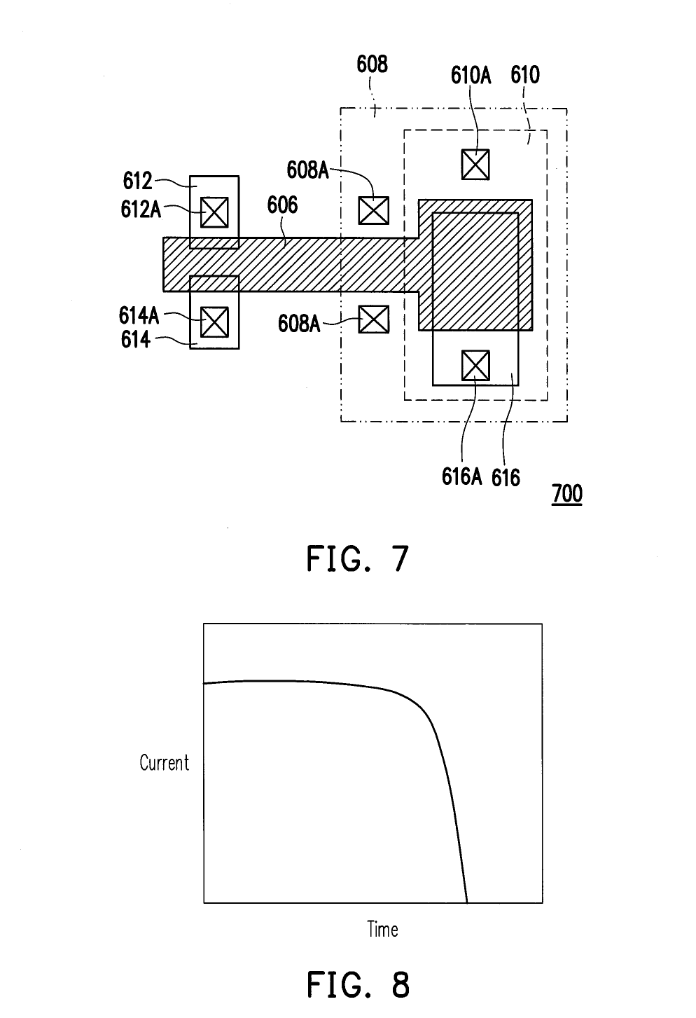

FIG. 7 is a top view diagram of a semiconductor device according to another exemplary embodiment of the invention. Referring to FIG. 7, the difference between the semiconductor device 700 in this exemplary embodiment and the semiconductor device 600 in the exemplary embodiment as shown in FIG. 6A is that the second conductive type well 608 of the semiconductor device 700 in this exemplary embodiment is electrically connected to two second well contact layers 608A. Further, these two second well contact layers 608A are configured between the N-type transistor, constituted with the N-type source diffusion layer 612, the N-type drain diffusion layer 614 and the P-type semiconductor substrate 602, and the P-type well 610. Hence, the N-type well region 608 works to suppress the invasion of depletion layer from the P-type well 610 to the channel region.

### Third Embodiment

FIG. 8 is a current-vs-time diagram illustrating the current flow between the N-type source diffusion layer 612 and the N-type drain diffusion layer 614 of the exemplary embodiment in FIG. 6A as a function of time. Referring to FIG. 8, assuming in this exemplary embodiment, there is no charge in the floating gate 606 and the threshold voltage of the semiconductor device 600 is Vt0 at neutral state, and after the semiconductor device 600 is erased and the elapse of time is initialized (initialization), the threshold voltage of the semiconductor device 600 is Vt1, where the threshold voltage Vt1 is less than the threshold voltage Vt0. In order to monitor the elapse of time after initialized, a read pulse voltage Vread and a sense pulse voltage Vsens are respectively applied to the control gate contact layer 616A and the drain contact layer 614A to detect the current flow between the N-type source diffusion layer 612 and the N-type drain diffusion layer 614. The first well contact layer 610A is biased negatively for reducing erroneous leakage current. Presently, the other contact layers are grounded. It is worthy to note that the read pulse voltage Vread must be between the threshold voltage Vt1 and Vt0.

Referring to FIG. 8, while the threshold voltage Vt1 of the semiconductor device 600 progressively increases with time, the electrically current between the N-type source diffusion layer 612 and the N-type drain diffusion layer 614 is maintained larger than a predetermined value initially. However, when the threshold voltage of the semiconductor device 600 attains the read pulse voltage Vread, the current between the N-type source diffusion layer 612 and the N-type drain diffusion layer 614 rapidly decreases. Hence, by adjusting the value of Vread−Vt1, the lifetime of the semiconductor device 600 can be arbitrarily set. This type of semiconductor device is known as the integrated battery-less electronic timer (IBLET). It is also worthy to note that, in this exemplary embodiment, the semiconductor device 600 is preferred to be an enhancement type transistor, which has a higher threshold voltage Vt0 at neutral state. In a case that Vt0 is higher than zero and Vt1 is lower than zero, IBLET is called “normally-off type”.

### Fourth Embodiment

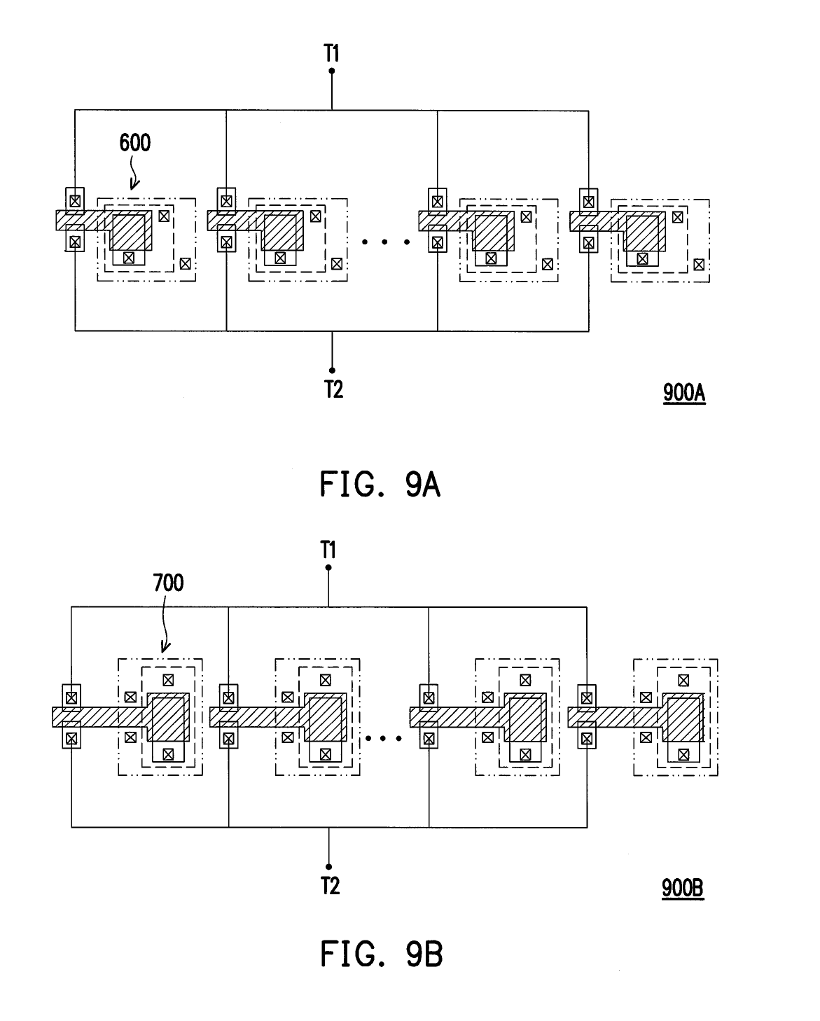

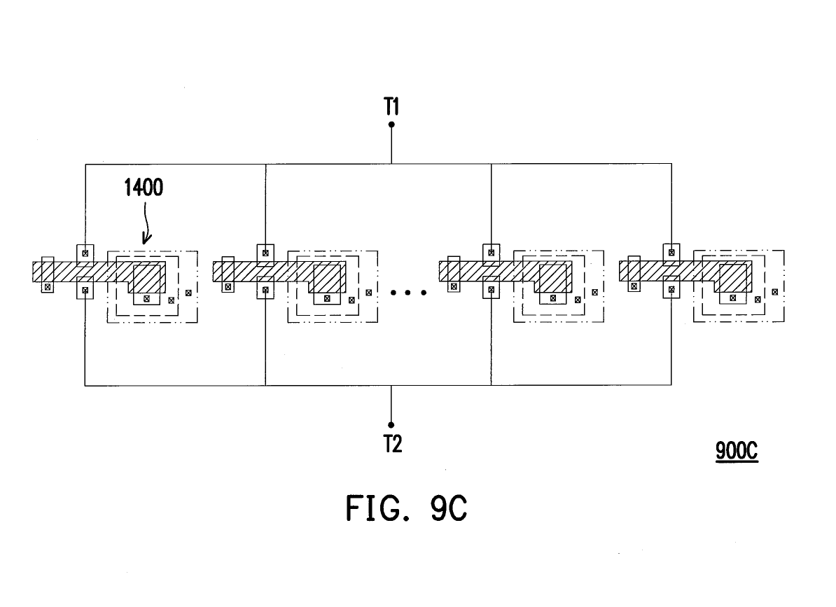

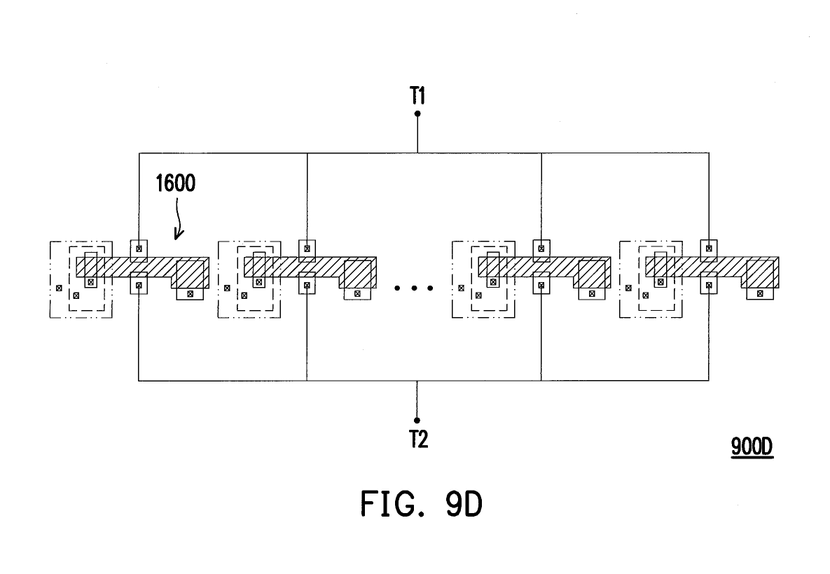

To resolve the problem of fluctuation of lifetime resulted from anomalous charge loss, a plurality of normally-off type battery-less electronic timers (which are semiconductor devices 600) may be connected in parallel. As shown in the parallel-chain circuit model in FIG. 9A, the parallel-chain circuit 900A includes a plurality of semiconductor devices 600, wherein the source contact layer 612 and the drain contact layer 614 of each semiconductor device 600 are respectively electrically connected to a first terminal T1 and a second terminal T2. Since anomalous charge loss occurring in the semiconductor device 600 shortens the lifetime of the semiconductor device 600, when a plurality of semiconductor devices is connected in parallel, the semiconductor device 600 having the longest lifetime in the parallel-chain circuit 900A determines the lifetime of the entire system.

### Fifth Embodiment

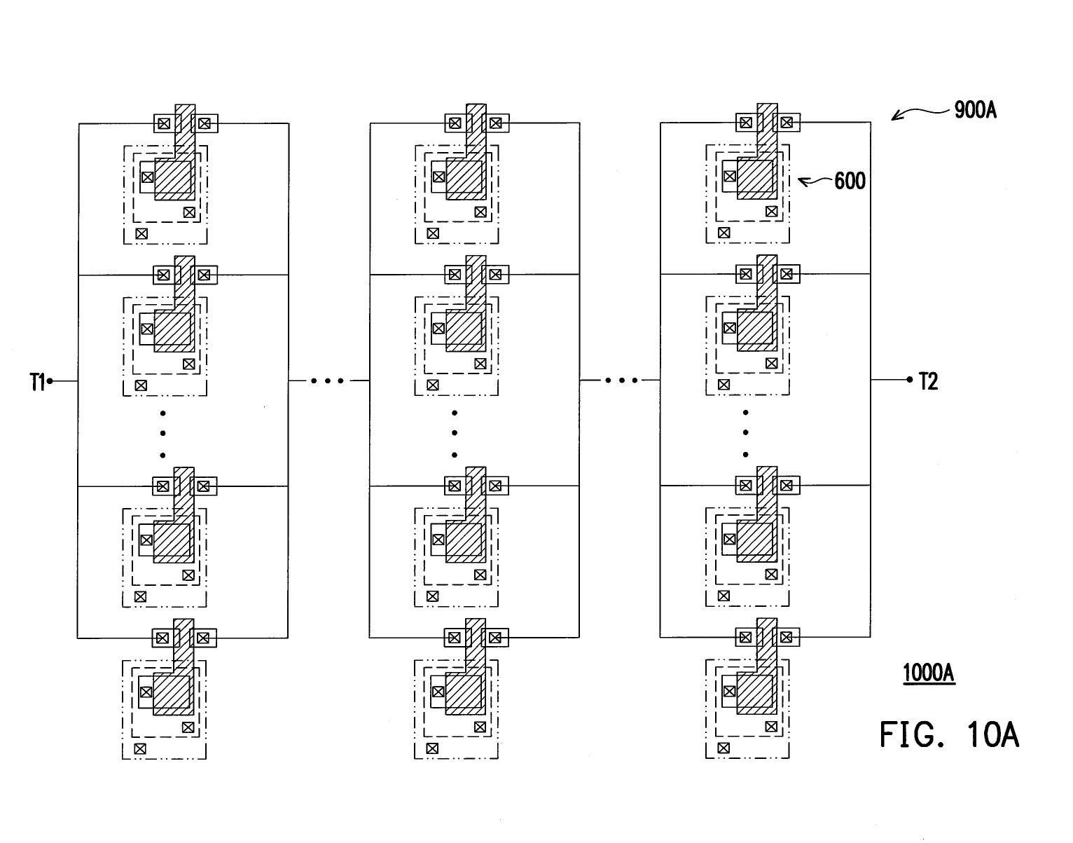

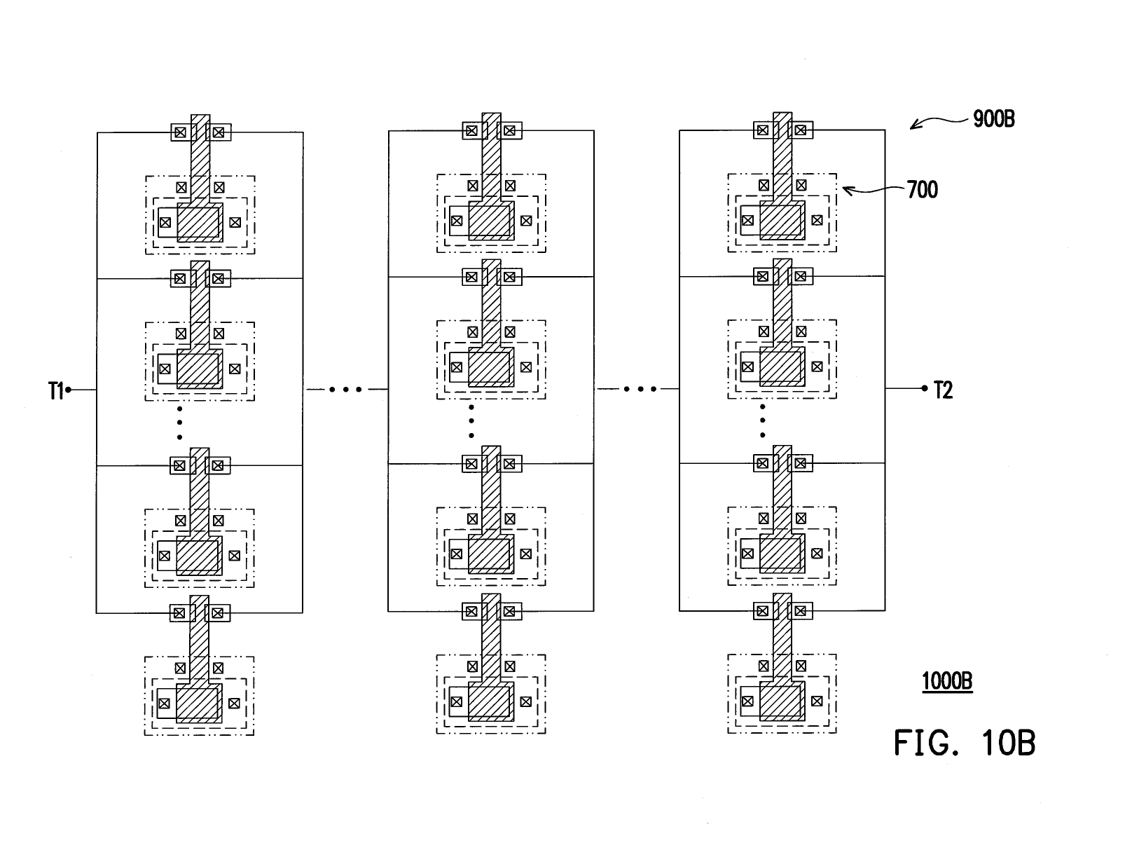

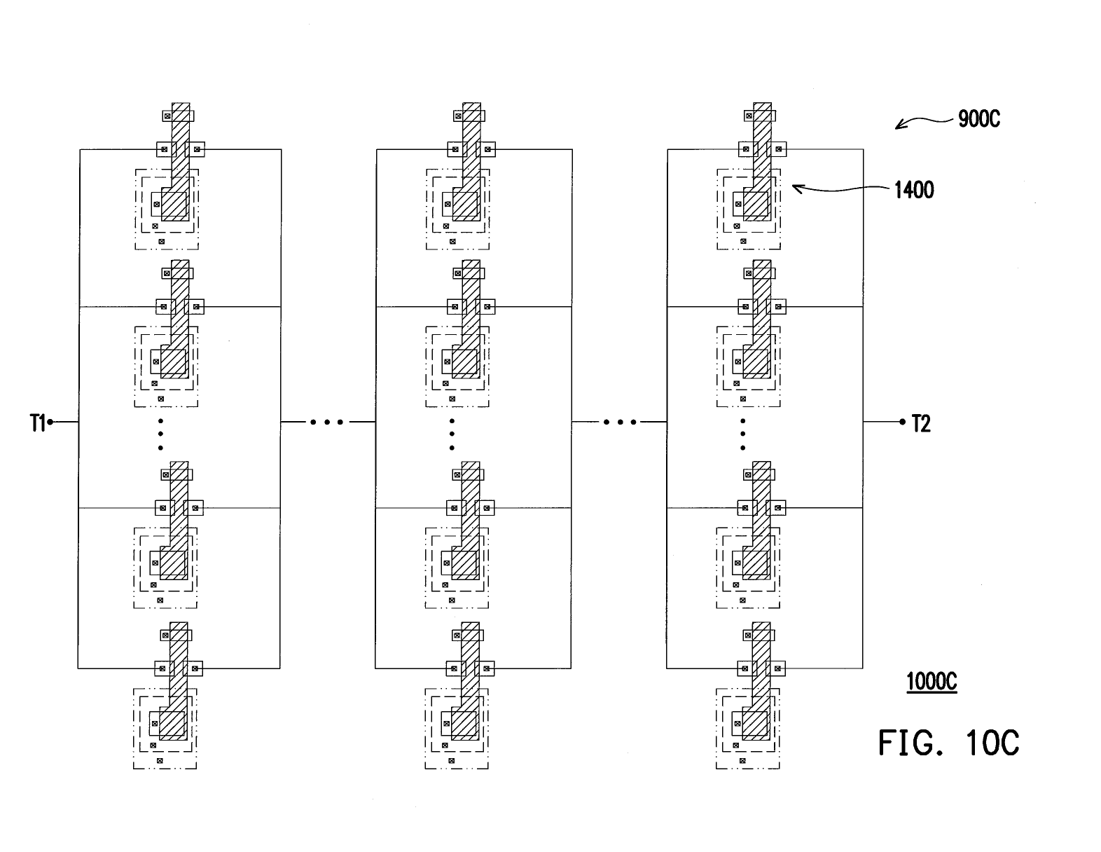

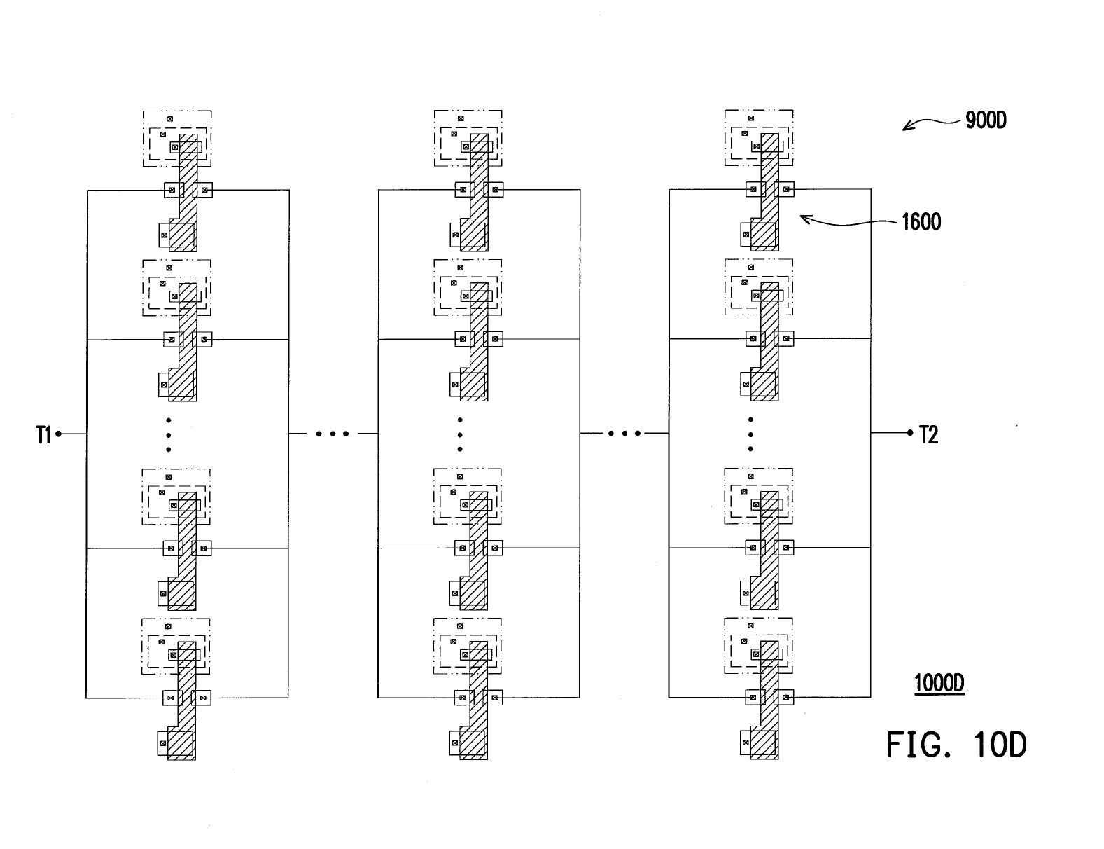

FIG. 10A is a schematic diagram showing a serial-connected parallel-chains circuit (1000A) consisted of parallel chain circuits 900A, according to another exemplary embodiment of the invention. Referring to FIG. 10A, the serial-connected parallel-chains circuit 1000A includes a plurality of parallel-chain circuits 900A that are serially connected. As shown in FIG. 10A, the system's lifetime is determined by the parallel chain circuit 900A whose lifetime is shortest among the parallel chain circuits 900A in the serial-connected parallel-chains circuit 1000A, in which the lifetime of each chain is determined by the longest lifetime among the semiconductor devices 600 therein. Assuming each parallel-chain circuit 900A is constituted with N semiconductor devices 600, and the serial-connected parallel-chains circuit 1000A includes M parallel-chain circuits 900A. We have the upper limit of M, in order to prevent the increase of the resistance of the serial-connected parallel-chains circuit 1000A. On the other hand, we have the lower limit of M in order to remove unknown statistical error factors from time-ticking precision. This invention makes the lifetime of the serial-connected parallel-chains circuit 1000A shorter than the longest lifetime of the N×M semiconductor devices 600 and longer than the average lifetime of the N×M semiconductor devices 600. Generally, based on the statistical consideration, M may be greater than 20, while N must also be greater than M.

### Sixth Embodiment

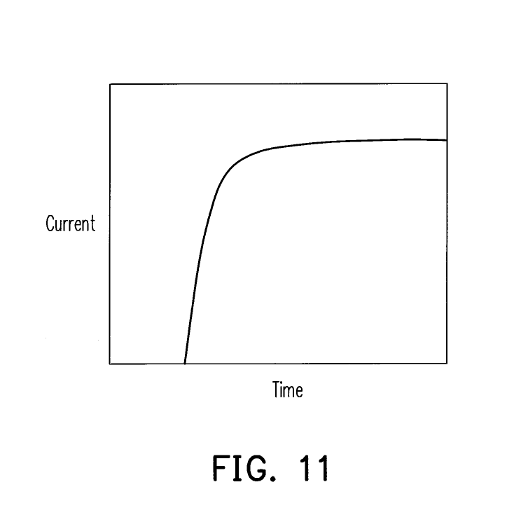

FIG. 11 is another current-vs-time diagram illustrating the current flow between the N-type source diffusion layer 612 and the N-type drain diffusion layer 614 of the exemplary embodiment in FIG. 6A as a function of'time. Referring to FIG. 11, the threshold voltage of the semiconductor device 600 in this exemplary embodiment is assumed to be Vt2, before the initialization of the semiconductor device 600 is performed. By programming the semiconductor device 600, the elapse of time is initialized (initialization), and the threshold voltage of the semiconductor device 600 becomes Vt3, which is greater than the initial threshold voltage Vt2. To read the elapse of time after initialization, read pulse Vread and sense pulse Vsens are respectively applied to the control gate contact layer 616A and the drain contact layer 614A to detect the current flow between N-type source diffusion layer 612 and N-type drain diffusion layer 614, while other contact layers are grounded. It is worthy to note that, the read pulse voltage Vread must be between the threshold voltage Vt3 and Vt2.

As shown in FIG. 11, while the threshold voltage Vt3 of the semiconductor device 600 progressively decreases with time, no current flow appears between the N-type source diffusion layer 612 and N-type diffusion layer 614 initially (before the lifetime). However, when the threshold voltage of the semiconductor device 600 decreases to be lower than the read pulse voltage Vread, the current flow between the N-type source diffusion layer 612 and the N-type drain diffusion layer 614 occurs. Hence, the lifetime of the semiconductor device 600 can be arbitrarily set by adjusting the value of Vt3-Vread. This type of semiconductor device 600 is known as “integrated battery-less electronic timer”. Moreover, in this exemplary embodiment, the semiconductor device is preferably a depletion type of transistor, in which the threshold voltage Vt2 is lower. In a case that Vt2 is lower than zero and Vt3 is higher than zero, IBLET is called “normally-on type”.

### Seventh Embodiment

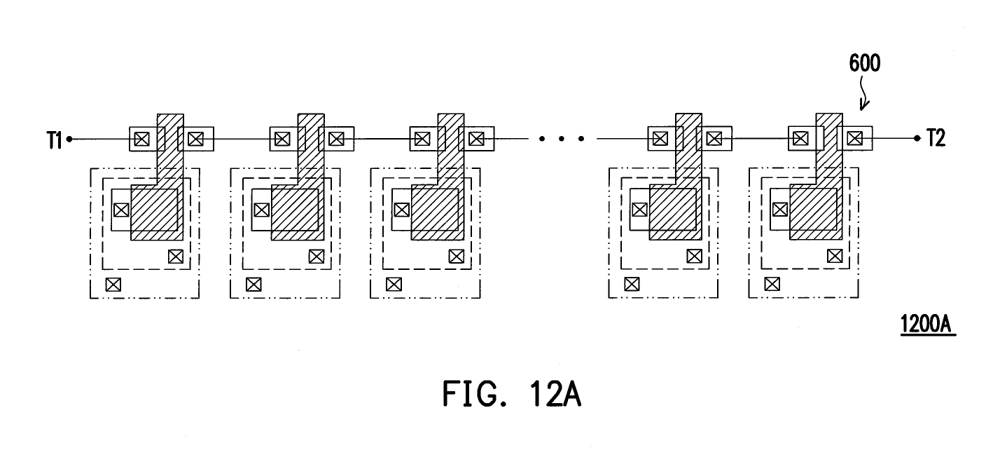

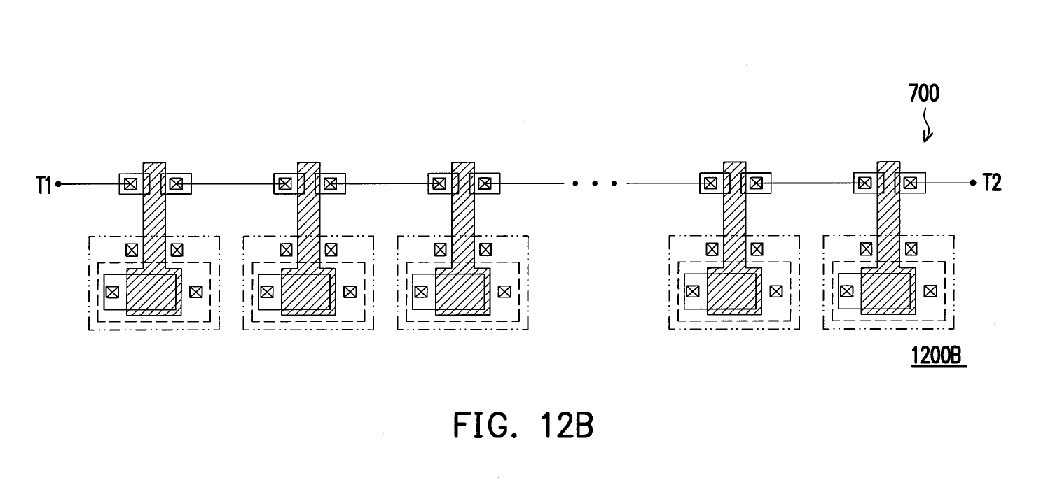

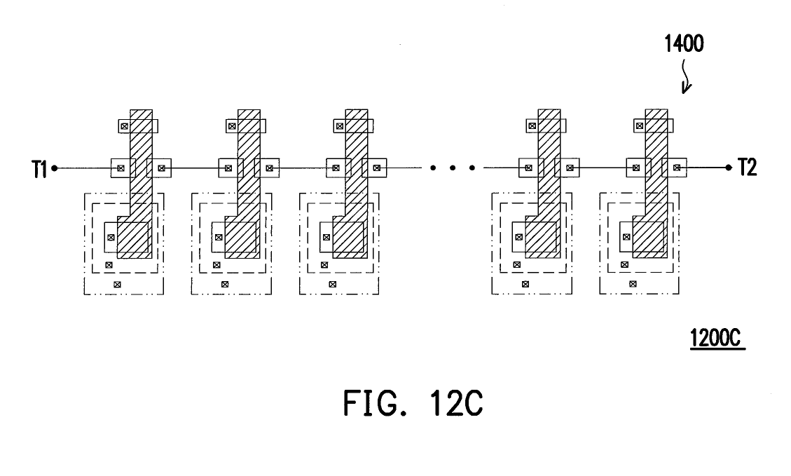

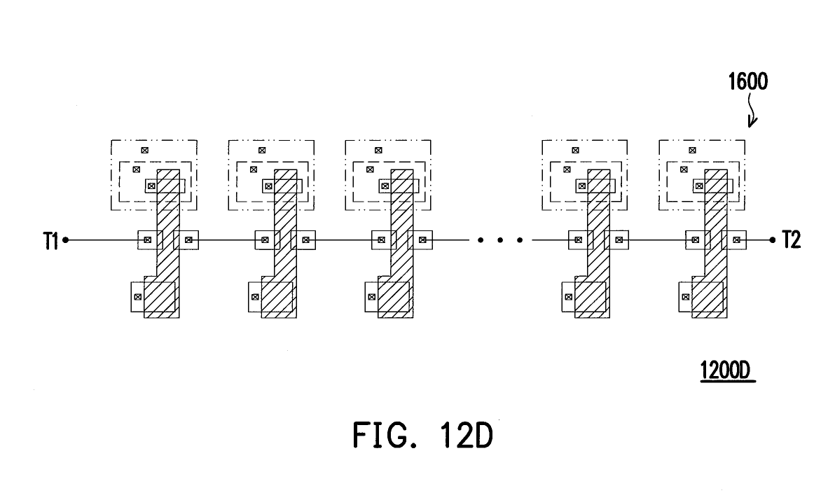

FIG. 12A is a serially connected circuit model according to another exemplary embodiment of the invention. The serial-chain circuit 1200A includes a plurality of normally-on type semiconductor devices 600 serially connected together, wherein the drain contact layer 614A of the first semiconductor device 600 in the serial-chain circuit 1200A is electrically connected to the first terminal T1. The source contact layer 612A of the last semiconductor device 600 in the serial-chain circuit 1200A is electrically connected to the second terminal T2. As long as the number of the serially connected semiconductor devices is sufficiently large in serial-chain circuit 1200A, the semiconductor device 600 whose lifetime is longest among the semiconductor devices 600 therein the serial-chain circuit 1200A determines the system's lifetime. Alternatively speaking, when the semiconductor device 600 whose lifetime is longest expires, the path between the first terminal T1 and the second terminal T2 becomes conductive.

### Eighth Embodiment

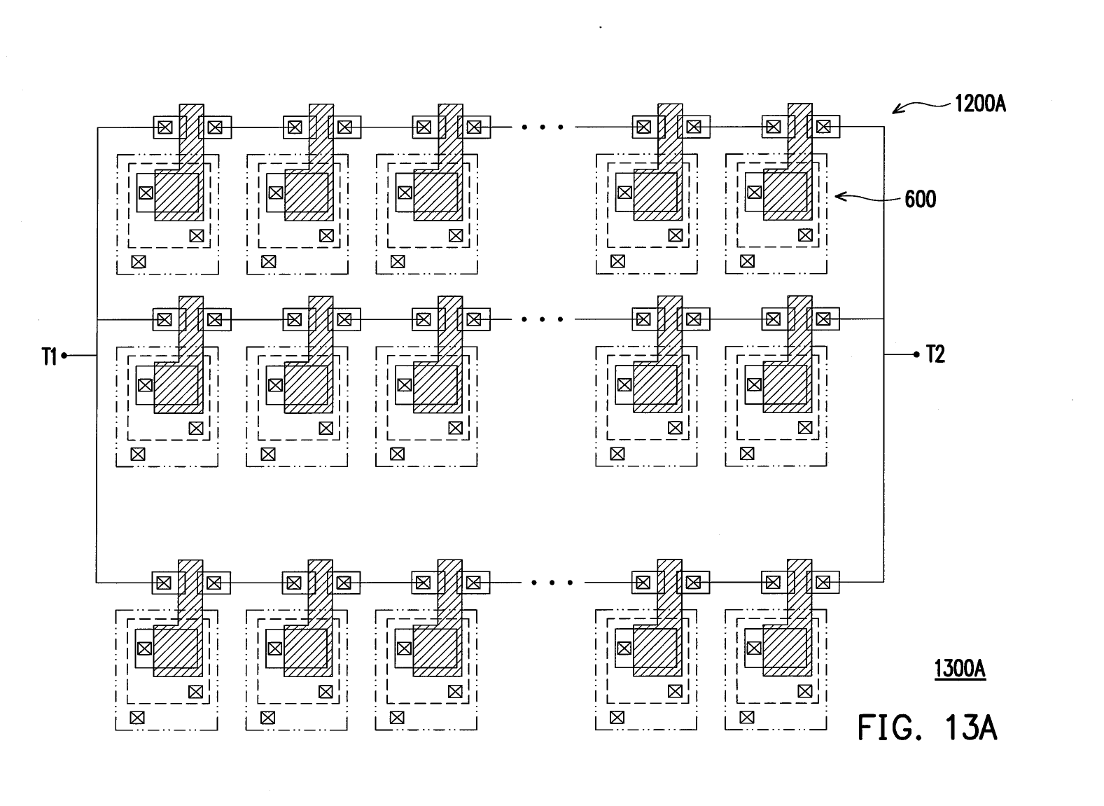

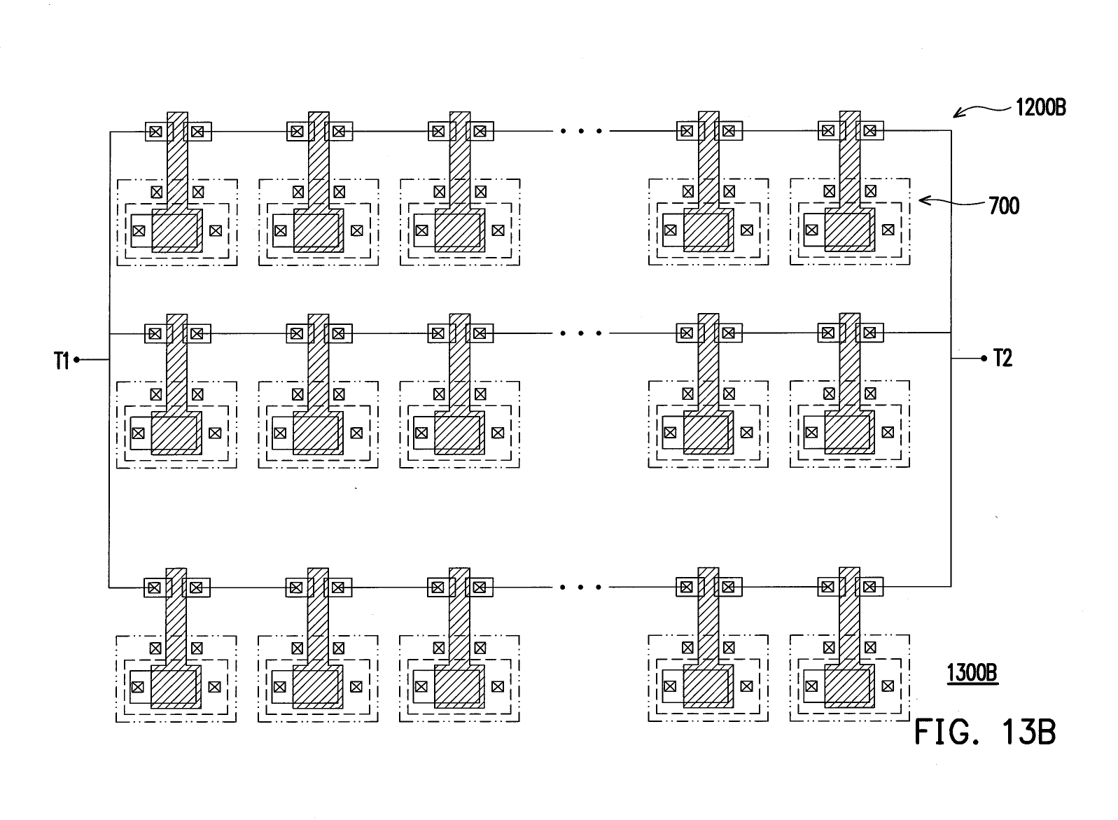

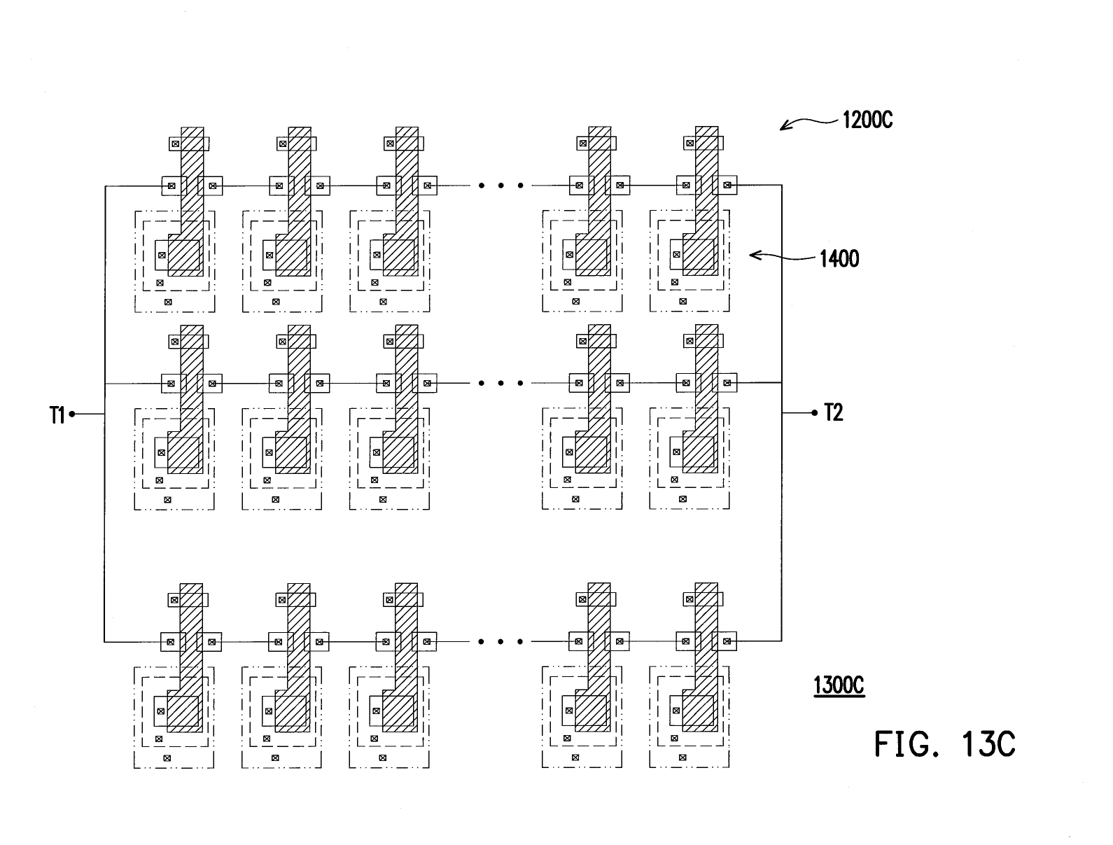

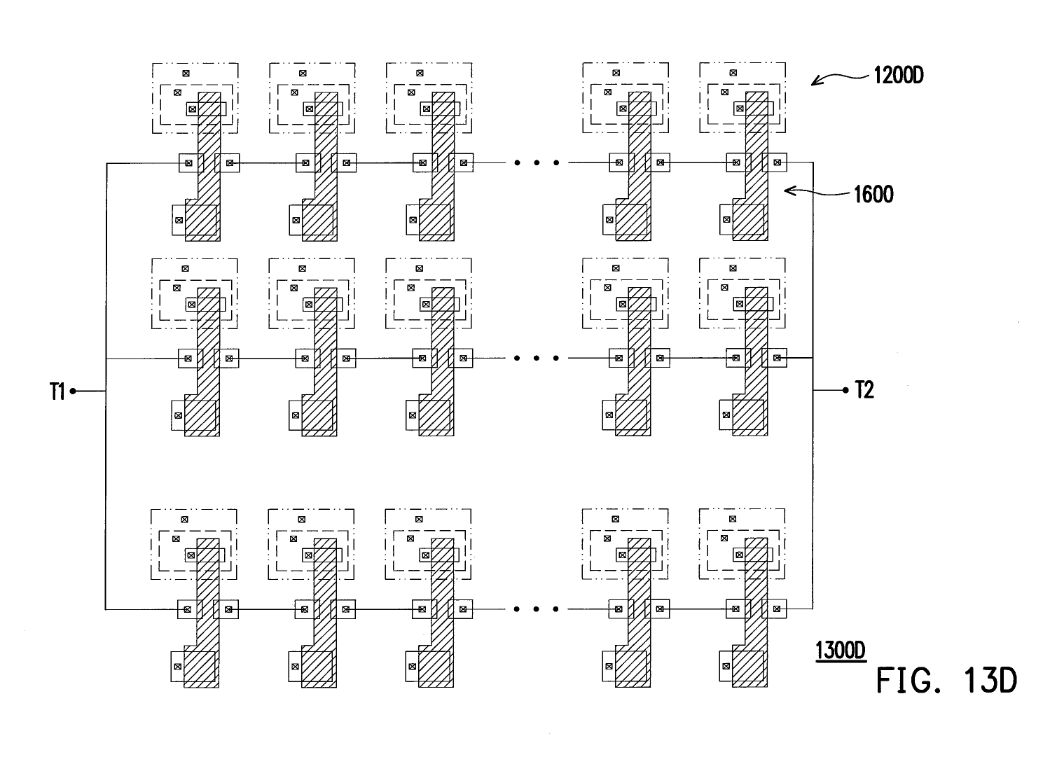

FIG. 13A is a schematic diagram showing a parallel-connected serial-chain circuit according to another exemplary embodiment of the invention. Referring to FIG. 13A, the parallel-connected serial-chain circuit 1300A includes a plurality of serial-chain circuits 1200A that are connected in parallel. As shown in FIG. 13A, the lifetime of the system is determined by the serial chain circuit 1200A whose lifetime is shortest among the parallel-connected serial-chain circuit 1300A therein, in which the lifetime of each serial-chain circuit 1200A is determined by the semiconductor devices 600 whose lifetime is longest therein serial-chain circuit 1200A. Assuming each serial-chain circuit 1200A is constituted with N semiconductor devices 600, and the parallel-connected serial chain circuit 1300A includes M parallel-connected serial-chain circuit 1200A. We have the lower limit of M, in order to remove unknown statistically error factors from the time-ticking precision. Otherwise, the parallel-connected serial-chain circuit 1300A may include the serial-chain circuits 1200A whose lifetime is abnormally long. This invention makes the lifetime of the parallel-connected serial-chain circuit 1300A shorter than the longest lifetime of the N×M semiconductor devices 600 and longer than the average lifetime of the N×M semiconductor devices 600. In general, based on the statistical consideration, M may be larger than 20, while N must be greater than M.

### Ninth Embodiment

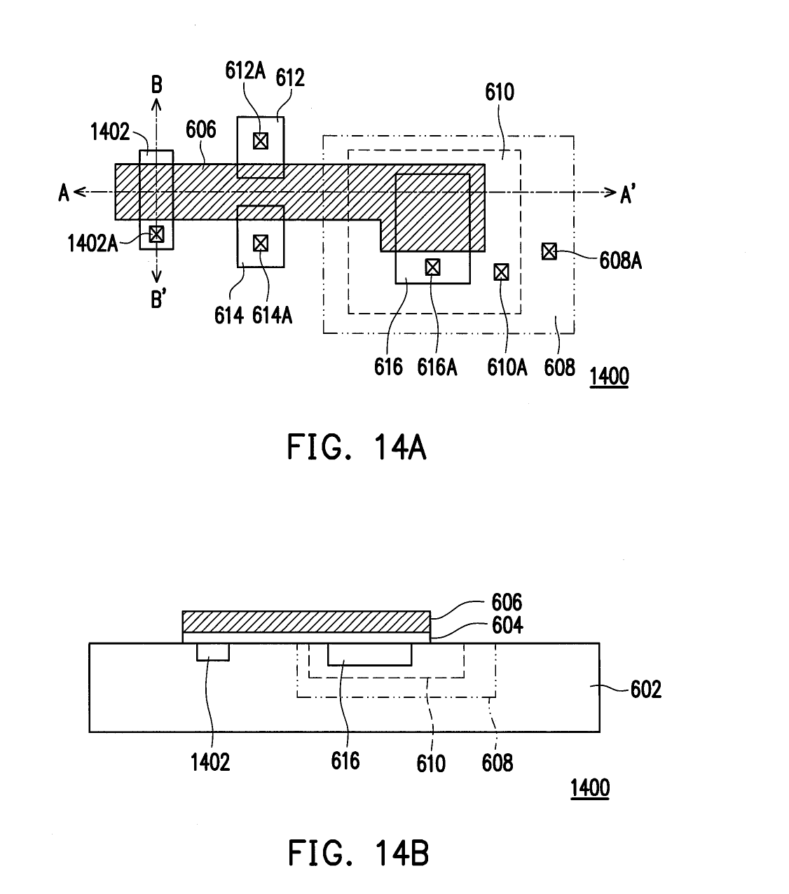

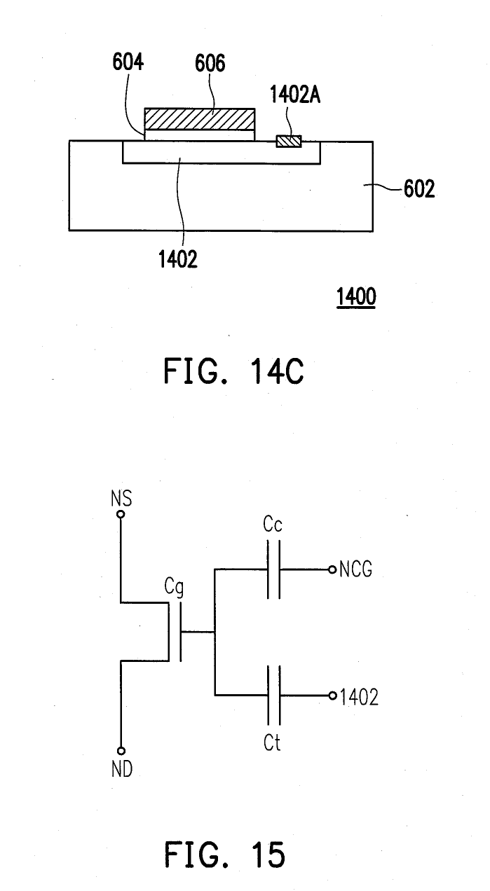

FIG. 14A is a top view diagram of a semiconductor device according to another exemplary embodiment of the invention. FIGS. 14B to 14C are cross-sectional views of FIG. 14A along the cutting lines A-A′, B-B′, respectively. Referring concurrently to FIGS. 14A, 14B and 14C, a difference between the semiconductor device 1400 in this exemplary embodiment and the semiconductor device 600 in the exemplary embodiment as shown in FIG. 6A is that the semiconductor device 1400 in this exemplary embodiment further includes a second conductive type complementary capacitor gate diffusion layer 1402 (which is an N-type complementary capacitor gate diffusion layer). The N-type complementary capacitor gate diffusion layer 1402 is formed in the P-type semiconductor substrate 602, at the exterior the N-type well region 608. Further, the N-type transistor constituted with the N-type source diffusion layer 612, N-type drain diffusion layer 614 and the floating gate 606 is configured between the N-type complementary capacitor gate diffusion layer 1402 and the N-type well 608. Further, the N-type complementary capacitor gate diffusion layer 1402 is electrically connected to a complementary capacitor gate contact layer 1402A. The equivalent circuit of semiconductor device 1400 of this exemplary embodiment is shown in FIG. 15, wherein the equivalent capacitance between the N-type complementary capacitor gate diffusion layer 1402 and the floating gate FG is depicted as Ct. It is worthy to note that, the control capacitance Cc is greater than the gate capacitance Cg plus the complementary capacitance Ct, i.e., Cc>Cg+Ct.

Specifically speaking, when the semiconductor device 1400 of the exemplary embodiment shown in FIGS. 14A to 14C performs the read, program and erase operations, the biases applied to the various contact layers are shown in the following Table 3:

TABLE 3

| | Read | Program | Erase |
|---|---|---|---|
| Control gate contact layer | Sweep | First bias | Negative |
| Source contact layer | Ground | Second bias | Ground |
| Drain contact layer | Positive | Second bias | Ground |
| First well region contact layer | Ground | Second bias | Negative |
| Second well region contact layer | Ground | Second bias | Ground |
| Complementary capacitor gate | Ground | Ground | Positive |
| contact layer | | | |
| Substrate contact layer | Ground | Ground | Ground |

As shown in Table 3, to read the threshold voltage shift, a sweep voltage is applied to the control gate contact layer 616A, while a positive bias is concurrently applied to the drain contact layer 614A and the other contact layers are grounded.

To program the semiconductor device 1400, a first bias is applied to the control gate contact layer 616A. A second bias is concurrently applied to the source contact layer 612A, the drain contact layer 614A, the first well contact layer 610A and the second well contact layer 608A. Further, the complementary capacitor gate contact layer 1402A and the substrate contact layer are grounded. The first bias is greater than ground, while the second bias is greater than or equal to ground, and is smaller than or equal to the first bias. Since the control capacitance Cc is greater than the sum of the gate capacitance Cg and the complementary capacitor capacitance Ct (Cc>Cg+Ct), electrons flow from the N-type complementary capacitor gate diffusion layer 1402 to the floating gate 606 through the gate dielectric layer 604. The floating gate 606 is negatively charged and the threshold voltage of the semiconductor device 1400 is thereby increased.

To erase the semiconductor device 1400, a negative bias is applied to the control gate contact layer 616A and the first well contact layer 610A. Concurrently, a positive bias is applied to the complementary capacitor gate contact layer 1402A, while other contact layers are grounded. Accordingly, electrons flow from the floating gate 606 to the N-type complementary capacitor gate diffusion layer 1402 through the gate dielectric layer 604 to positively charge the floating gate 606. The threshold voltage of the semiconductor device 1400 is thereby decreased.

### Tenth Embodiment

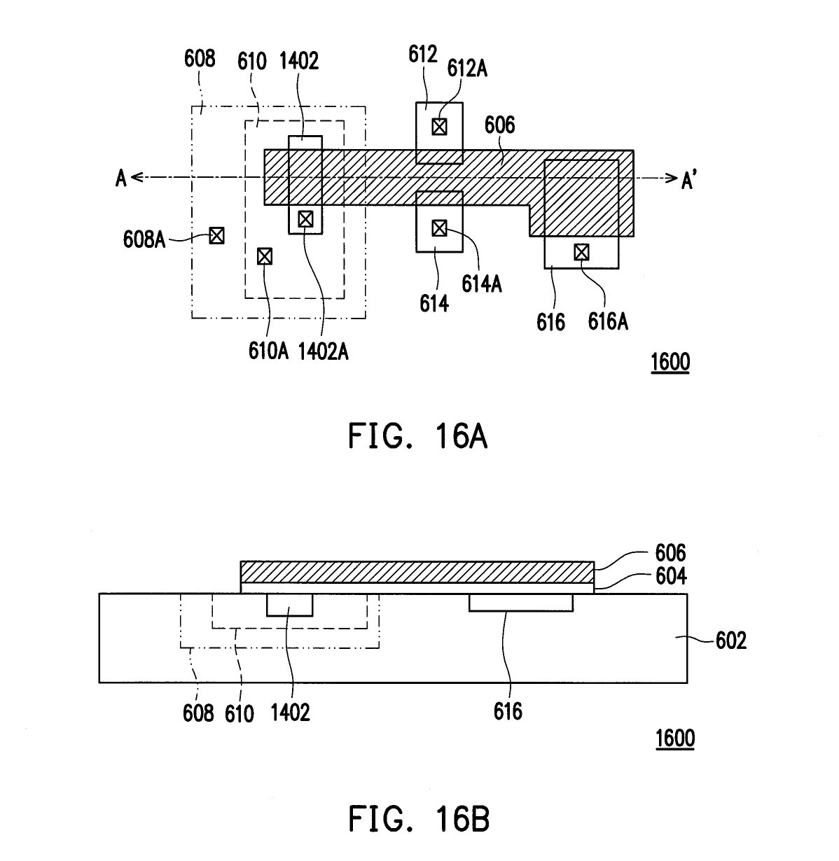

FIG. 16A is a top view diagram of a semiconductor device according to another exemplary embodiment of the invention. FIG. 16B is a cross-sectional view diagram of FIG. 16A along the cutting line A-A′. Referring concurrently to FIGS. 16A to 16B, a difference between the semiconductor device 1600 of this exemplary embodiment and the semiconductor device 1400 as shown in FIG. 14A is that the diffusion layer formed in the P-type well 610 is the N-type complementary capacitor gate diffusion layer 1402, while the N-type control gate diffusion layer 616 that is originally formed in the P-type well region 610 in the exemplary embodiment in FIG. 14 is directly formed in the P-type semiconductor substrate 602, at the exterior of the N-type well 608. Moreover, the equivalent circuit of the semiconductor device 1600 of this exemplary embodiment is shown in FIG. 15, in which the control capacitance Cc is greater than the gate capacitance Cg plus the channel capacitance Ct.

More specifically, the operation method of the semiconductor device 1600 of the exemplary embodiment as illustrated in FIGS. 16A to 16B is exemplified in Table 4 below.

TABLE 4

| | Read | Program | Erase |
|---|---|---|---|
| Control gate contact layer | Sweep | Positive | Ground |
| Source contact layer | Ground | Ground | Ground |
| Drain contact layer | Positive | Ground | Ground |
| First well region contact layer | Ground | Negative | 2^{nd} bias or Ground |
| Second well region contact | Ground | Ground | 2^{nd} bias or Ground |
| layer | | | |
| complementary capacitor gate | Ground | Negative | 1^{st} bias |
| contact layer | | | |
| Substrate contact layer | Ground | Ground | Ground |

As shown in Table 4, to read the threshold voltage shift of the semiconductor device, a sweep bias is applied to the control contact layer 616A and a positive bias is applied to the drain contact layer 614A, while other contact layers are grounded.

To program the semiconductor device 1600, a positive bias is applied to the control gate contact layer 616A, and a negative bias is concurrently applied to the first well contact layer 610A and the complementary capacitor gate contact layer 1402A, respectively, while other contact layers are grounded. It is worthy to note that, since the control capacitance Cc is greater than the sum of the gate capacitance Cg and the tunnel capacitance Ct (Cc>Cg+Ct), electrons flow from the N-type complementary capacitor gate diffusion layer 1402 to the floating gate 606 through the gate dielectric layer 604 to negatively charge the floating gate 606. Accordingly, the threshold voltage of the semiconductor device 1400 is increased.

To erase the semiconductor device 1600, a first bias is applied to the complementary capacitor gate contact layer 1402A, and a second bias is concurrently applied to the first well contact layer 610A and the second well contact layer 608A, while the other contact layers are grounded. Further, the first bias is greater than ground, while the second bias is greater than or equal to ground, and less than or equal to the first bias. Accordingly, electrons flow from the floating gate 606 to the N-type complementary capacitor gate diffusion layer 1402 through the gate dielectric layer 604 to positively charge the floating gate 606. As a result, the threshold voltage of the semiconductor device 1400 is decreased.

It is worthy to note that, although the above illustrated exemplary embodiments herein refer to the operation methods and the application circuits of a semiconductor device with the first conductive type being the P-conductive type and the second conductive type being the N-conductive type, it is to be understood that these embodiments are presented by way of example and not by way of limitation. In other exemplary embodiments, the first conductive type is N-conductive type, while the second conductive type is the P-conductive type. Further, the shape of the floating gate disclosed herein is presented by way of example and not by way of limitation. It is to be appreciated that, as long as the equivalent capacitance generated by the control gate diffusion layer is greater than the other capacitance of which dielectric film electrons tunnel through, a floating gate of other shapes can be implemented in accordance with the invention. Additionally, the parallel chain circuit 900A, the serial connected parallel-chain circuit 1000A, the serial chain circuit 1200A, the parallel connected serial-chain circuit 1300A are constructed with the semiconductor device 600. However, it should be appreciated that the invention is not limited as such. Parallel chain circuits 900B-900D as shown in FIG. 9B-9D, The semiconductor device 600 in the parallel chain circuit 900A could be replaced by the semiconductor device 700, the semiconductor device 1400 or the semiconductor device 1600 as disclosed in the exemplary embodiments in FIGS. 7, 14A and 16A, respectively. Serial connected parallel-chain circuits 1000B˜1000D as shown in FIG. 10B˜10D, The semiconductor device 600 in the serial connected parallel-chain circuit 1000A could be replaced by the semiconductor device 700, the semiconductor device 1400 or the semiconductor device 1600, respectively. Serial chain circuits 1200B˜1200D as shown in FIG. 12B˜12D, The semiconductor device 600 in the serial chain circuit 1200A could be replaced by the semiconductor device 700, the semiconductor device 1400 or the semiconductor device 1600, respectively. Parallel connected serial-chain circuits 1300B˜1300D as shown in FIG. 13B˜13D. The semiconductor device 600 in the parallel connected serial-chain circuit 1300A could be replaced by the semiconductor device 700, the semiconductor device 1400 or the semiconductor device 1600, respectively.

In accordance to the exemplary embodiments disclosed herein, by applying a bias to the second conductive type well and the first conductive type well, and enhancing the dopant distribution in the first conductive type semiconductor substrate, leakage current from the second conductive type control gate diffusion layer to the second conductive type source diffusion layer and the second conductive type drain diffusion layer is mitigated. It is noteworthy to say that, in the semiconductor device of the exemplary embodiments disclosed herein, the isolation layers are precluded. Accordingly, in order to suppress the leakage current between the second conductive type control gate diffusion layer, the second conductive type source diffusion layer and the second conductive type drain diffusion layer, we introduced the first conductive type well and the second conductive type well. This substantially decreases the production cost of integrated battery-less electronic timer.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A semiconductor device, comprising:
a first conductive type semiconductor substrate;
a gate dielectric layer, formed in the first conductive type semiconductor substrate;
a floating gate, formed on the gate dielectric layer;
a second conductive type well, formed in the first conductive type semiconductor substrate;
a first conductive type well, formed in the second conductive type well;
a second conductive type source diffusion layer and a second conductive type drain diffusion layer, respectively formed at two sides of the floating gate in the first conductive type semiconductor substrate, wherein the second conductive type source diffusion layer, the second conductive type drain diffusion layer and the floating gate are formed to compose a second conductive type transistor, and the second conductive type transistor configured outside the second conductive type well; and
a second conductive type control gate diffusion layer, formed in the first conductive type well.

2. The semiconductor device of claim 1 further comprising:
a source contact layer, disposed on the second conductive type source diffusion layer;
a drain contact layer, disposed on the second conductive type drain diffusion layer;
a control gate contact layer, disposed on the second conductive type control gate diffusion layer;
at least a second well contact layer, disposed on the second conductive well;
a first well contact layer, disposed on the first conductive type well; and
a substrate contact layer, disposed on the first conductive type semiconductor substrate.

3. The semiconductor device of claim 1, wherein the second well contact layer is configured between the second conductive type transistor and the first conductive type well.

4. The semiconductor device of claim 1, wherein an overlapping area of the floating gate and the second conductive type control gate diffusion layer is greater than an overlapping area of the floating gate and the second conductive type transistor's channel area on the surface of the first conductive type semiconductor substrate between the source contact layer and the drain contact layer.

5. An operation method of the semiconductor device of claim 1, the method comprising:
when reading a charged state of the semiconductor device, applying a sweep bias to the control gate contact layer, grounding the source contact layer and the substrate contact layer, applying a positive bias to the drain contact layer, applying a negative bias to the first well contact layer, and applying a positive bias to or grounding the second well contact layer;
when programming the semiconductor device, applying a first bias to the control gate contact layer, grounding the source contact layer, the drain contact layer and the substrate, applying a second bias to or grounding the first well contact layer and the second well contact layer, wherein the first bias is greater than ground, and the second bias is greater than or equal to the ground and is less than or equal to the first bias; and
when erasing the semiconductor device, applying a negative bias to the control gate contact layer and the first well contact layer, applying a positive bias to the source contact layer and the drain contact layer, and grounding the second well contact layer and the substrate contact layer.

6. A semiconductor device, comprising:
a first conductive type semiconductor substrate;
a gate dielectric layer, formed on the first conductive type semiconductor substrate;
a floating gate, formed on the gate dielectric layer;
a second conductive type well, formed in the first conductive type semiconductor substrate;
a first conductive type well, formed in the second conductive type well;
a second conductive type complementary capacitor gate diffusion layer, formed in the first conductive type semiconductor substrate, outside the second conductive well;
a second conductive type source diffusion layer and a second conductive type drain diffusion layer, respectively formed at two sides of the floating gate in the first conductive type semiconductor substrate, wherein the second conductive type source diffusion layer, the second conductive type drain diffusion layer and the floating gate are formed to compose a second conductive type transistor, and the second conductive type transistor configured between the second conductive type well and the second conductive type complementary capacitor gate diffusion layer; and
a second conductive type control gate diffusion layer, formed in the first conductive type well.

7. The semiconductor device of claim 6 further comprising:
a source contact layer, disposed on the second conductive type source diffusion layer;
a drain contact layer, disposed on the second conductive type drain diffusion layer;
a control gate contact layer, disposed on the second conductive type control gate diffusion layer;
at least a second well contact layer, disposed on the second conductive well;
a first well contact layer, disposed on the first conductive type well;
a substrate contact layer, disposed on the first conductive type semiconductor substrate; and
a complementary capacitor gate contact layer, disposed on the second conductive type complementary capacitor gate diffusion layer.

8. An operation method of the semiconductor device of claim 7, the method comprising:
when reading a charged state of the semiconductor device, applying a sweep bias to the control gate contact layer, applying a positive bias to the drain contact layer, grounding the source contact layer, the first well contact layer, the second well contact layer, the complementary capacitor gate contact layer and the substrate contact layer;
when programming the semiconductor device, applying a first bias to the control gate contact layer, applying a second bias to the source contact layer, the drain contact layer, the first well contact layer and the second well contact layer, grounding the complementary capacitor gate contact layer and the substrate contact layer, wherein the first bias is greater than ground, and the second bias is greater than or equal to the ground and is less than or equal to the first bias; and
when erasing the semiconductor device, applying a negative bias to the control gate contact layer and the first well contact layer, grounding the source contact layer, the drain contact layer, the second well contact layer and the substrate contact layer, and applying a positive bias to the complementary capacitor gate contact layer.

9. A semiconductor device, comprising:
a first conductive type semiconductor substrate;
a gate dielectric layer, formed on the first conductive type semiconductor substrate;
a floating gate, formed on the gate dielectric layer;
a second conductive type well, formed in the first conductive type semiconductor substrate;
a first conductive type well, formed in the second conductive type well;
a second conductive type complementary capacitor gate diffusion layer, formed in the first conductive type well;
a second conductive type control gate diffusion layer, formed in the first conductive type substrate and at an exterior of the second conductive well; and
a second conductive type source diffusion layer and a second conductive type drain diffusion layer, respectively formed at two sides of the floating gate in the first conductive type semiconductor substrate, wherein the second conductive type source diffusion layer, the second conductive type drain diffusion layer and the floating gate are formed to compose a second conductive type transistor, and the second conductive type transistor configured between the second conductive type well and the second conductive type control gate diffusion layer.

10. The semiconductor device of claim 9 further comprising:
a source contact layer, disposed on the second conductive type source diffusion layer;
a drain contact layer, disposed on the second conductive type drain diffusion layer;
a control gate contact layer, disposed on the second conductive type control gate diffusion layer;
at least a second well contact layer, disposed on the second conductive well;
a first well contact layer, disposed on the first conductive type well;
a substrate contact layer, disposed on the first conductive type semiconductor substrate; and
a complementary capacitor gate contact layer, disposed on the second conductive type complementary capacitor gate diffusion layer.

11. An operation method of the semiconductor device of claim 10, the operation method comprising:
when reading a charged state of the semiconductor device, applying a sweep bias to the control gate contact layer, applying a positive bias to the drain contact layer, and grounding the source contact layer, the first well contact layer, the second well contact layer, the substrate contact layer, and the complementary capacitor gate contact layer;
when programming the semiconductor device, applying a positive bias to the control gate contact layer, applying a negative bias to the first well contact layer and the complementary capacitor gate contact layer, grounding the source contact layer, the drain contact layer, the second well contact layer, and the substrate contact layer; and
when erasing the semiconductor device, applying a first bias to the complementary capacitor gate contact layer, applying a second bias to the first well contact layer and the second well contact layer, grounding the control gate contact layer, the source contact layer, the drain contact layer, and the substrate contact layer, wherein the first bias is greater than ground, and the second bias is greater than or equal to the ground and is smaller than or equal to the first bias.

12. A parallel chain circuit comprising a plurality of the semiconductor devices of claim 2, wherein the source contact layer and the drain contact layer of each semiconductor device of the plurality of the semiconductor devices are electrically connected to a first terminal and a second terminal, respectively.

13. A serial-connected parallel-chain circuit comprising a plurality of the parallel chain circuits of claim 12, wherein the plurality of the parallel chain circuits are connected in series.

14. A parallel chain circuit comprising a plurality of the semiconductor devices of claim 7, wherein the source contact layer and the drain contact layer of each semiconductor device of the plurality of the semiconductor devices are electrically connected to a first terminal and a second terminal, respectively.

15. A serial-connected parallel-chain circuit comprising a plurality of the parallel chain circuits of claim 14, wherein the plurality of the parallel chain circuits are connected together in series.

16. A parallel circuit comprising a plurality of the semiconductor devices of claim 10, wherein the source contact layer and the drain contact layer of each semiconductor device of the semiconductor devices are electrically connected to a first terminal and a second terminal, respectively.

17. A serial-connected parallel-chain circuit comprising a plurality of the parallel chain circuits of claim 16, wherein the plurality of parallel chain circuits are connected together in series.

18. A serial chain circuit comprising a plurality of the semiconductor devices of claim 2, serially connected together, wherein the drain contact layer of a first semiconductor device of the semiconductor devices in the serial chain circuit is electrically connected to a first terminal and the source contact layer of a last semiconductor device of the semiconductor devices in the serial chain circuit is electrically connected to a second terminal.

19. A parallel-connected serial-chain circuit comprising a plurality of the serial chain circuits of claim 18, wherein the plurality of the serial chain circuits are connected in parallel.

20. A serial chain circuit, comprising a plurality of the semiconductor devices of claim 7, wherein the plurality of the semiconductor devices are connected in series, and the drain contact layer of a first semiconductor device of the semiconductor devices in the serial chain circuit is electrically connected to a first terminal, and the source contact layer of a last semiconductor device of the semiconductor devices in the serial chain circuit is electrically connected to a second terminal.

21. A parallel-connected serial-chain circuit comprising a plurality of the serial circuits of claim 20, wherein the plurality of the serial chain circuits are connected together in parallel.

22. A serial chain circuit comprising a plurality of the semiconductor devices of claim 10, wherein the plurality of the semiconductor devices are connected in series, and the drain contact layer of a first semiconductor device of the semiconductor devices in the serial chain circuit is electrically connected to a first terminal, and the source contact layer of a last semiconductor device of the semiconductor devices in the serial chain circuit is electrically connected to a second terminal.

23. A parallel-connected serial-chain circuit comprising a plurality of the serial chain circuits of claim 22, wherein the plurality of the serial chain circuits are connected in parallel.
